(19) United States
(12) Patent Application Publication
(10) Pub. No.: US 2010/0012953 A1
(43) Pub. Date: Jan. 21, 2010

(54) OPTICAL SEMICONDUCTOR DEVICE

(75) Inventor: Hidenori Saito, Fukuoka-ken (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/500,027

(22) Filed: Jul. 9, 2009

(30) Foreign Application Priority Data
Jul. 15, 2008 (JP) 2008-184081

(51) Int. Cl. H01L 31/167

(52) U.S. Cl. 257/82; 257/E31.108; 257/E33.076

(57) ABSTRACT

First and second optical semiconductor elements are respectively mounted on first and second mount beds. First and second lead terminals are respectively arranged around the first and the second mount beds. The second lead terminals extend along the first lead terminals. The first and second lead terminals are electrically connected to the first and second optical semiconductor elements through first and second connection conductors, respectively. The second mount bed is arranged at an interval from the first optical semiconductor element, and extends along the first mount bed. The second mount bed has a penetration hole at a portion corresponding to a light emitting or light receiving surface of the first optical semiconductor element. The second lead terminals are bent so as to be laminated on the first lead terminal. The second lead terminals are fixed to the first lead terminal at portions via insulating material.

### CROSS-REFERENCE TO RELATED APPLICATION

This application is based upon and claims the benefit of priority from the prior Japanese Patent Applications No. 2008-184081, filed on Jul. 15, 2008, the entire contents of which are incorporated herein by reference.

### BACKGROUND OF THE INVENTION

The present invention relates to an optical semiconductor device equipped with optical semiconductor elements.

An optical semiconductor device is used in a communication equipment to perform optical communication using infrared light. The optical semiconductor device is provided with a transmitting unit having a light emitting element and a receiving unit having a light receiving element. The transmitting unit and receiving unit are arranged adjacently to each other and are molded by resin and are integrated.

An optical semiconductor device disclosed in the Japanese Patent Application Publication (Kokai) No. 10-70304 uses a first and second leadframe. A light emitting element and a driver chip are die bonded on the first leadframe. A light receiving element and an output signal processing chip are die bonded on the second leadframe. The light emitting element and the light receiving element are covered with transparent resin, respectively. Non-transparent resin is formed between the light emitting element and the light detecting element to prevent light passing from the former to the latter.

In recent years, with progress of miniaturization and slimming down of an electronic device, reduction of a mounting area on a substrate is required for the optical semiconductor device.

Since a transmitting unit and a receiving unit are arranged adjacently to each other in the optical semiconductor device disclosed in the patent publication, a mounting area for the two units is needed. As a result, sufficient miniaturization can not be achieved.

Another optical semiconductor device is disclosed in the Japanese Patent Application Publication (Kokai) No. 2007-180275. The optical semiconductor device is equipped with a main leadframe and an auxiliary frame. The auxiliary frame is arranged apart from the main leadframe at an interval to oppose to each other.

An optical semiconductor element is mounted on the main leadframe. A lens is mounted on the auxiliary frame. The optical semiconductor element is covered with transparent resin which is provided between the main leadframe and the auxiliary frame.

A lead terminal of the auxiliary frame and a lead terminal of the main leadframe are joined to connect the auxiliary frame and the main leadframe electrically.

The optical semiconductor device disclosed in the patent publication has either a light emitting element or light receiving element as the optical semiconductor element. The patent publication does not show using both a light emitting element and a light receiving element arranged apart from each other.

### BRIEF SUMMARY OF THE INVENTION

According to an aspect of the invention, an optical semiconductor device is provided, which comprises a first optical semiconductor element, a first mount bed on which the first optical semiconductor element is mounted, first lead terminals arranged around the first mount bed, the first lead terminals being electrically connected to the first optical semiconductor element through first connection conductors, a second optical semiconductor element, a second mount bed to mount a second optical semiconductor element, the second mount bed being arranged at an interval from the first optical semiconductor element and extending along the first mount bed, the second mount bed having a penetration hole at a portion corresponding to a light emitting or light receiving surface of the first optical semiconductor element, and second lead terminals arranged around the second mount bed and extending along the first lead terminals, the second lead terminals being electrically connected to the second optical semiconductor element through second connection conductors, the second lead terminals being bent so as to be laminated on the first lead terminals, the second lead terminals being fixed to the first lead terminal at a portion via an insulating material.

According to another aspect of the invention, an optical semiconductor device is provided, which comprises a first optical semiconductor element, a first mount bed on which the first optical semiconductor element is mounted, the first mount bed having a first penetration hole which is covered with a light emitting or light receiving surface of the first optical semiconductor element, first lead terminals arranged around the first mount bed, the first lead terminals being electrically connected to the first optical semiconductor element through first connection conductors, a second optical semiconductor element, a second mount bed to mount the second optical semiconductor element, the second mount bed being placed on a side opposite to the first optical semiconductor element and extending along the first mount bed, the second mount bed being fixed to first mount bed via an insulating material, the second mount bed having a second penetration hole at a portion corresponding to the first optical semiconductor element to expose the first penetration hole, and second lead terminals arranged around the second mount bed and extending along the first lead terminals, the second lead terminals being electrically connected to the second optical semiconductor element through second connection conductors, the second lead terminals being laminated on and fixed to the first lead terminal via the insulating material.

According to further another aspect of the invention, an optical semiconductor device is provided, which comprises a first optical semiconductor element, a first mount bed on which the first optical semiconductor element is mounted, first lead terminals arranged around the first mount bed, the first lead terminals being electrically connected to the first optical semiconductor element through first connection conductors;

a second optical semiconductor element, a second mount bed to mount a second optical semiconductor element, the second mount bed being placed on the first lead terminals and extending in the same direction as the first mount bed, the second mount bed being fixed to the first lead terminals via an insulating material, a portion of the second mount bed being cut corresponding to the areas of the first mount bed and end portions of the first lead terminals, and second lead terminals arranged around the second mount bed and extending along the first lead terminals, the second lead terminals being fixed to the first lead terminals via the insulating material, the second lead terminals being laminated on the first lead terminal and connected to the second optical semiconductor element through second connection conductors.

### BRIEF DESCRIPTION OF THE DRAWINGS

FIG. 1 is a plan view showing a first embodiment of an optical semiconductor device according to the present invention.

FIG. 2 is a view of a section taken along a plane A-A of FIG. 1 and seen in a direction of an arrow.

FIG. 3 is a view of a section taken along a plane B-B of FIG. 1 and seen in a direction of an arrow.

FIG. 4 is a perspective view showing the first embodiment of the optical semiconductor device according to the present invention.

FIG. 5A and FIG. 5B show a plan view and a view of section taken along a plane U-U of FIG. 5A, which show a manufacturing step of the first embodiment, respectively.

FIG. 6A and FIG. 6B show a plain view and a view of section taken along a plane V-V of FIG. 6A, which show a manufacturing step of the first embodiment, respectively.

FIG. 7 and FIG. 8 are sections showing manufacturing steps of the first embodiment, respectively.

FIG. 9 is a plan view showing a second embodiment of an optical semiconductor device according to the present invention.

FIG. 10 is a view of a section taken along a plane C-C of FIG. 9 and seen in a direction of an arrow.

FIG. 11 is a view of a section taken along a plane D-D of FIG. 9 and seen in a direction of an arrow.

FIG. 12A and FIG. 12B show a plan view and a view of section taken along a plane W-W of FIG. 12A, which show a manufacturing step of the second embodiment, respectively.

FIG. 13A and FIG. 13B show a plain view and a view of section taken along a plane X-X of FIG. 13A, which show a manufacturing step of the second embodiment, respectively.

FIG. 14 and FIG. 15 are sections showing manufacturing steps of the second embodiment, respectively.

FIG. 16 is a plan view showing a third embodiment of an optical semiconductor device according to the present invention.

FIG. 17 is a view of a section taken along a plane E-E of FIG. 16 and seen in a direction of an arrow.

FIG. 18 is a view of a section taken along a plane F-F of FIG. 16 and seen in a direction of an arrow.

FIG. 19A and FIG. 19B show a plan view and a view of section taken along a plane Y-Y of FIG. 19A, which show a manufacturing step of the third embodiment, respectively.

FIG. 20A and FIG. 20B show a plain view and a view of section taken along a plane V-V of FIG. 20A, which show a manufacturing step of the third embodiment, respectively.

FIG. 21 and FIG. 22 are sections showing manufacturing steps of the second embodiment, respectively.

### DETAILED DESCRIPTION OF THE INVENTION

Embodiments of a present invention will be described hereinafter with reference to the accompanying drawings.

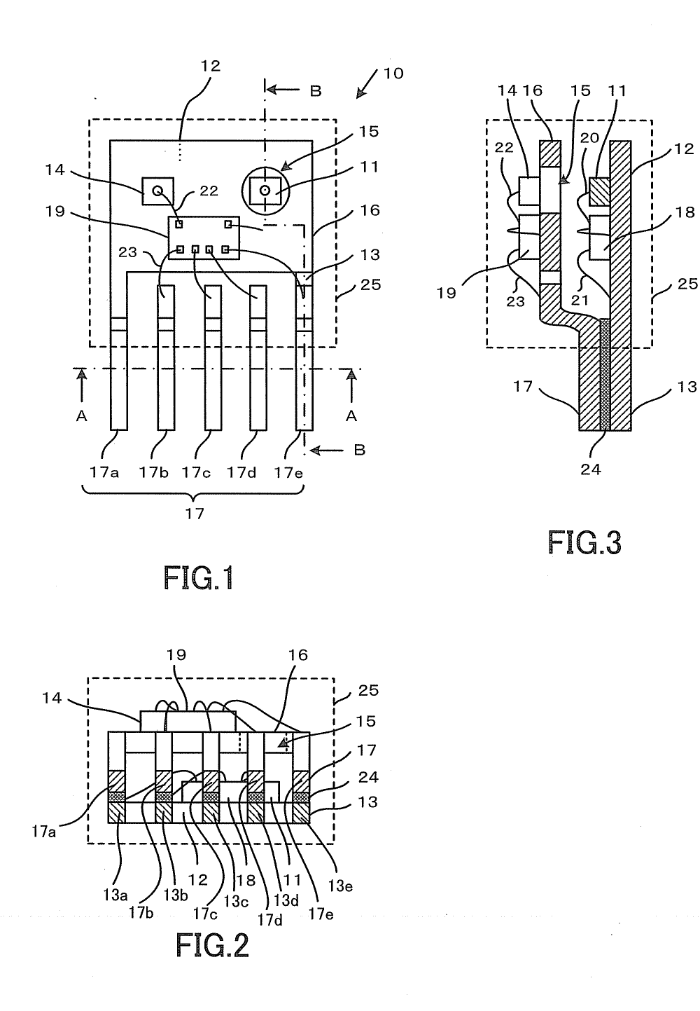

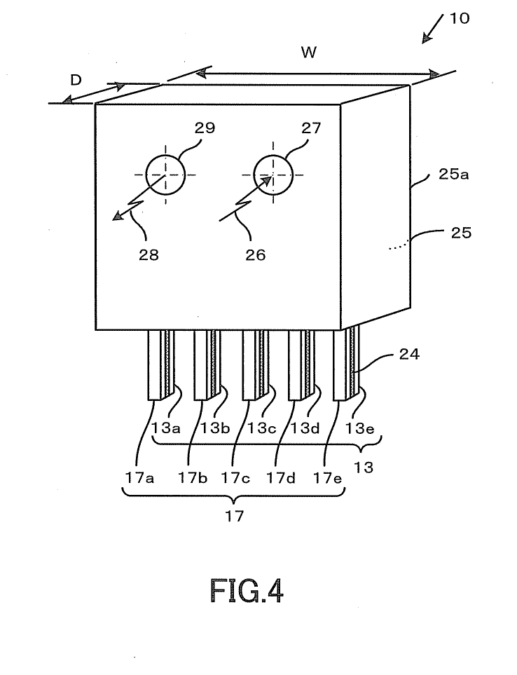

An optical semiconductor device of a first embodiment of a present invention will be explained. FIG. 1 is a plan view showing the first embodiment of the optical semiconductor device according to the present invention. FIG. 2 is a view of a section taken along a plane A-A of FIG. 1 and seen in a direction of an arrow. FIG. 3 is a view of a section taken along a plane B-B of FIG. 1 and seen in a direction of an arrow. FIG. 4 is a perspective view showing the first embodiment of the optical semiconductor device according to the present invention.

An optical semiconductor device according to this embodiment is an optical transmission device which can perform interactive communication. The optical semiconductor device is provided with a light emitting element and a light receiving element arranged in opposition to each other. The optical semiconductor device contains a driver chip to drive the light emitting element, and contains a signal processing chip to process output signal of the light receiving element.

As shown in FIGS. 1 to 3, an optical semiconductor device 10 of the embodiment is provided with a first optical semiconductor element 11. The device 10 has a first mount bed 12 and first lead terminals 13a, 13b, 13c, 13d, 13e of a first lead terminal portion 13. The first optical semiconductor element 11 is mounted on a first mount bed 12. A light emitting or receiving surface of the first semiconductor element 11 faces upward.

The first lead terminals 13a, 13b, 13c, 13d, 13e are provided around the first mount bed 12, and are electrically connected to the first optical semiconductor element 11 through first connection conductors, respectively. The optical semiconductor device 10 is provided with a second optical semiconductor element 14. The device 10 has a second mount bed 16 and second lead terminals 17a to 17e of a second lead terminal poriton 17. The second optical semiconductor element 14 is mounted on the second mount bed 16 to be positioned apart from the first optical semiconductor element 11 at an interval.

A light emitting or receiving surface of the second semiconductor element 14 faces upward. The second mount bed 16 has a penetration hole 15 corresponding to the position of the light emitting or receiving surface of the first optical semiconductor element 11. The second lead terminals 17a to 17e are arranged around the second mount bed 16, and extend along the first lead terminals 13a, 13b, 13c, 13d, 13e.

The second lead terminals 17a to 17e are electrically connected to the second optical semiconductor element 14 through second connection conductors. The second lead terminal portion 17 is bent so as to laminated on the first lead terminal portion 13 and is partially fixed to the first lead terminal portion 13 via insulators 24.

The first optical semiconductor element 11 may be a silicon photo diode to receive a light signal transmitted from the outside. The second optical semiconductor device 14 may be an infrared light emitting element of GaAlAs which transmits a light signal to the outside. Instead of the silicon photo diode, other photo diodes may be used. Instead of the infrared light emitting element, a red LED or a semiconductor laser such as a VCSEL may be used.

The optical semiconductor device 10 has a first semiconductor chip 18 which is mounted on the first mount bed 12. The first semiconductor chip 18 has a function to process an output signal of the first optical semiconductor device 11 and to output a processing result to the outside. The optical semiconductor device 10 has a second semiconductor chip 19 which is mounted on the second mount bed 16. The second semiconductor chip 19 has a function to process a signal to transmit and to drive the second optical semiconductor element 14. The first semiconductor chip 18 may be a light receiving IC. The second semiconductor chip 19 may be a driver IC.

The first optical semiconductor element 11 is connected to a signal input terminal of the first semiconductor chip 18 through a wire 20. The first semiconductor chip 18 is connected to the first lead terminals 13a to 13d through wires 21.

The second optical semiconductor element 14 is connected to an driving output terminal of the second semiconductor chip 19 through a wire 22. The second semiconductor chip 19 is connected to the second lead terminals 17b to 17e through wires 23.

Portions of the second lead terminals 17a to 17e extend along and are laminated on the first lead terminals 13a to 13e. The portions and the first lead terminals 13a to 13e sandwich an insulating material 24, insulating resin, for example, to fix the portions of the first lead terminals.

The first and second optical semiconductor elements 11, 14, the first and second semiconductor chips 18, 19 and the first and second mount beds 12, 16 are molded and integrated by the transparent resin 25. The transparent resin 25 allows light of a light emitting wavelength of the second optical semiconductor element 14 to pass.

Ends of the first lead terminals 13a to 13e and the second lead terminals 17a to 17e are extended outside from a side of the resin 25.

As shown in FIG. 4, the optical semiconductor device 10 is covered with the resin 25. The optical semiconductor device 10 is provided with a sleeve 27 for allowing a light 26 to go to the first optical semiconductor element 11 from outside. The device is provided with a sleeve 29 for allowing a light 28 to be transmitted outside from the second optical semiconductor element 14. A resin 25a, which is opaque to visible light and infrared light, is further fitted in and fixed to the resin 25. The resins 25, 25a constitute a package.

The light 26 transmitted from outside can be irradiated to the first optical semiconductor element 11 through an optical fiber (not shown), which is inserted in the sleeve 27.

The light 28 emitted from the second optical semiconductor element 14 can be transmitted outside through an optical fiber (not shown) inserted in the sleeve 29.

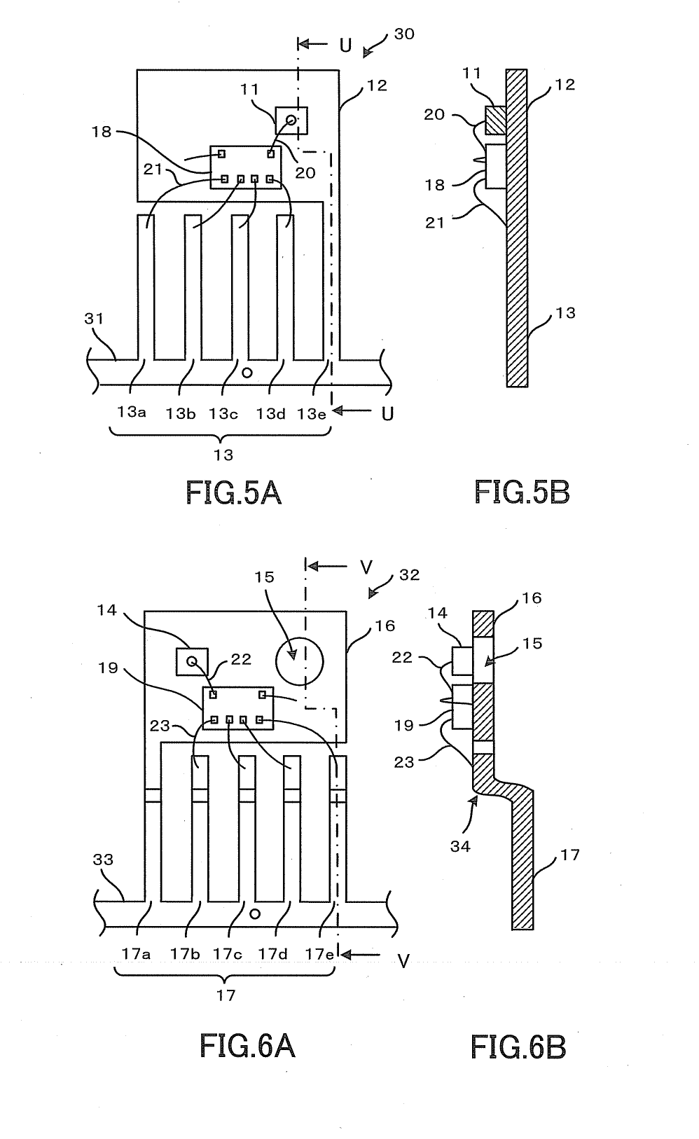

A method of manufacturing the optical semiconductor device 10 will be explained. FIG. 5A and FIG. 5B show a plan view and a view of section taken along a plane U-U of FIG. 5A, respectively. FIG. 5A and FIG. 5B show a manufacturing step of the first embodiment, respectively. FIG. 6A and FIG. 6B show a plain view and a view of section taken along a plane V-V of FIG. 6A, respectively. FIG. 6A and FIG. 6B show a manufacturing step of the first embodiment, respectively.

As shown in FIG. 5A and FIG. 5B, a first leadframe 30 is prepared. The first leadframe 30 has a first mount bed 12 and the first lead terminals 13a to 13e. The first lead terminal 13e is used as a ground terminal which extends from the first mount bed 12 in a direction. The first lead terminals 13a to 13d are arranged in parallel to the first lead terminal 13e. The first lead terminals 13a to 13e are mechanically connected by a tie bar 31.

A first optical semiconductor element 11 and a first semiconductor chip 18 are mounted on the first mount bed 12 using electrically conductive adhesive, for example, silver paste. The first optical semiconductor device 11 and a signal input terminal of the first semiconductor chip 18 are wire bonded with a wire 20. The first semiconductor chip 18 is wire bonded to the first lead terminals 13a to 13d with wires 21.

As shown in FIG. 6A and FIG. 6B, a second leadframe 32 is prepared. The second leadframe 32 has a second mount bed 16 and a second lead terminal 17a which is used as a ground terminal. The second lead terminal 17a extends from the second mount bed 16 in a direction. Second lead terminals 17b to 17e are arranged in parallel with the second lead terminal 17a. The second lead terminals 17a to 17e is connected by a tie bar 33.

Bending portions 34 are formed in the second leadframe 32. The portions are bent at the middles of the second lead terminals 17a to 17e to be formed in a shape of a crank

A second optical semiconductor element 14 and a second semiconductor chip 19 are mounted on the second mount bed 16 using electrically conductive adhesive. The second optical semiconductor element 14 is wire bonded to an output terminal of the second semiconductor chip 19 with a wire 22. The second semiconductor chip 19 is wire bonded to the second lead terminals 17b to 17e with wires 23.

In FIG. 5A and FIG. 5B, the first leadframe 30 is a copper plate plated with nickel and silver layers of about a 0.15 mm thickness. The first mount bed 12 and the first lead terminals 13a to 13e are formed by press processing. The second leadframe 32 has the same structure and is fabricated by the same process as the first leadframe 30.

The first mount bed 12 has a rectangle-shape approximately. The first optical semiconductor element 11 is mounted on one side from the central portion of the first mount bed 12. The first semiconductor chip 18 is adjacent to the first optical semiconductor element 11 and is mounted on the first mount bed 12 so as to be arranged on a side of the first lead terminals 13a to 13e.

The second mount bed 16 shown in FIG. 6A and FIG. 6B has the same shape as the first mount bed 12. The second optical semiconductor element 14 is mounted on the second mount bed 16 of the other side from the central portion of the first mount bed 16. The second semiconductor chip 19 is adjacent to the second optical semiconductor element 14, and is mounted on the second mount bed 16 so as to be arranged on a side of the second lead terminals 17a to 17e.

The connection portion of the first mount bed 12 and the first lead terminal 13e and the wires 20, 21 constitute the first connection conductors. The connection portion of the second mount bed 16 and the second lead terminal 17a and the wires 22, 23 constitute the second connection conductors.

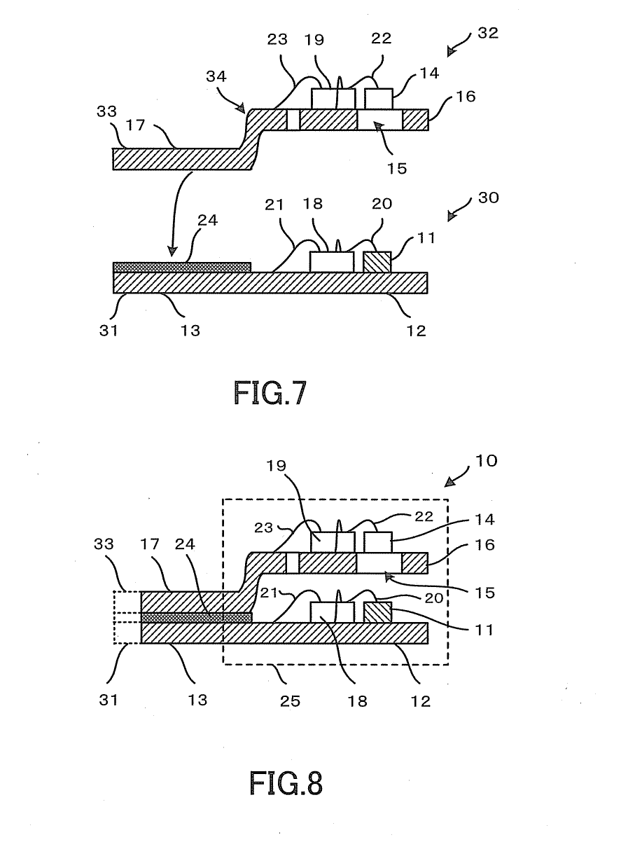

As shown in FIG. 7, an insulating paste, for example, a thermosetting epoxy resin is applied as the insulating material 24 onto the first lead terminals 13a to 13e and the tie bar 31.

The second leadframe 32 is aligned with and arranged above the first leadframe 30. The second leadframe 32 is dropped down to the first leadframe 30. The first lead terminals 13a to 13e and the tie bar 31 are laminated on the second lead terminals 17a to 17e and the tie bar 33, with the insulating material 24 sandwiched.

The insulating paste is cured. The first lead terminals 13a to 13e and the tie bar 31 are fixed to the second lead terminals 17a to 17e and the tie bar 33 via the insulating material 24.

As shown in FIG. 8, the first and second optical semiconductor elements 11 and 14, the first and second semiconductor chips 18 and 19, and the first and second mount beds 12 and 16 are molded and integrated by a the transparent resin 25. The resin 25 allows light of a light emitting wavelength of the second optical semiconductor element 14 to pass.

After a resin 25a is fitted in and fixed to the resin 25, an optical semiconductor device 10 is obtained by cutting the tie bars 31 and 33.

A width W of the optical semiconductor device 10 shown in FIG. 4 may be reduced by half approximately, compared with the case where the first leadframe 30 and the second leadframe 32 are arranged side by side on a plane.

On the other hand, a depth D of the optical semiconductor device 10 may be increased to be equal to or less than twice of the depth of the above case. The width W is larger than the depth D. The reduced width of the width W may be larger than the increased depth of the depth D. As a result, the mounting area (D×W) can be reduced.

As explained above, according to the optical semiconductor device 10 of the embodiment, the second leadframe 32 is laminated on and fixed to the first leadframe 30. The second lead terminals 17a to 17e of the second leadframe 32 are bent in order to form a shape of a crank.

The width W of the optical semiconductor device of the embodiment can be reduced compared with the optical semiconductor device where two leadframes are arranged side by side and molded and integrated. Therefore, The optical semiconductor device may be small.

In the embodiment, the first optical semiconductor element 11 is a light receiving element, and the second optical semiconductor element 14 is a light emitting element. The first optical semiconductor element 11 may be a light emitting element, and the second optical semiconductor device 14 may be a light receiving element.

Both the first optical semiconductor element 11 and the second optical semiconductor element 14 may be light receiving elements or light emitting elements.

In the embodiment, the first optical semiconductor element 11 and the second optical semiconductor element 14 are arranged apart from each other in a direction orthogonal to the lead terminals. The elements 11 and 14 can be positioned apart from each other in a direction parallel to the lead terminals.

In the embodiment, the first and second semiconductor chips 18 and 19 are arranged in the optical semiconductor device 10. The first and second semiconductor chips 18 and 19 may be arranged outside. In the case, the first and second optical semiconductor elements 11 and 14 are directly connected to the first and the second lead terminals through the wires.

The optical semiconductor device 10 is a Single Inline Package (SIP) where-lead terminals extend in a direction. The optical semiconductor device may be a Dual Inline Package (DIP) where lead terminals extend in a direction and in the reverse direction. The optical semiconductor device may be a package where lead terminals extend in four directions.

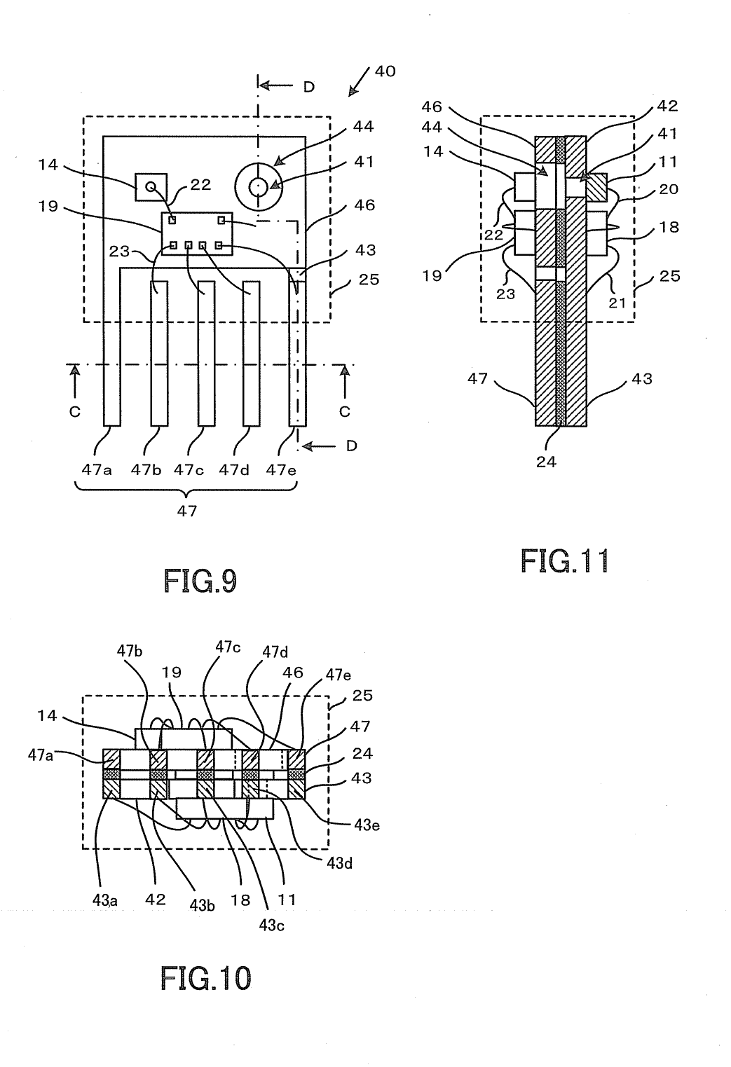

An optical semiconductor device of a second embodiment of a present invention will be explained. FIG. 9 is a plan view showing a second embodiment of an optical semiconductor device according to the present invention. FIG. 10 is a view of a section taken along a plane C-C of FIG. 9 and seen in a direction of an arrow. FIG. 11 is a view of a section taken along a plane D-D of FIG. 9 and seen in a direction of an arrow.

In the embodiment, the same reference numbers as those of the first embodiment indicate the same portions, respectively.

In the embodiment, the first and second leadframes are arranged back to back.

A first optical semiconductor element 11 is mounted on a first mount bed 42. The first mount bed 42 has a first penetration hole 41. The light emitting or light receiving surface of the first optical semiconductor element 11 covers the first penetration hole 41. A first lead terminal portion 43 having first lead terminals 43a to 43e is arranged around the first mount bed 42 and electrically connected to the first optical semiconductor element 11 through first connection conductors.

A second mount bed 46 are arranged in parallel to the first mount bed 42, and placed on an opposite side of the first optical semiconductor element 11. The second mount bed 46 is fixed to the first mount bed 42 via insulating material 24. A light emitting or light receiving surface of a second semiconductor element 14 faces upward. The second mount bed 46 has a second penetration hole 44 which oppose to the first penetration hole 41 to be positioned at a portion corresponding to the first optical semiconductor element 11.

A second lead terminal portion 47 having second lead terminals 47a to 47e is arranged around the second mount bed 46 to extend in parallel to the first lead terminal portion 43, and are electrically connected to the second optical semiconductor element 14 through second connection conductors. The second lead terminal portion 47 is placed on the first lead terminal portion 43, and is fixed to the first lead terminal portion 43 via the insulating material 24.

Since the first optical semiconductor element 11 is mounted on the first mount bed 42 so that the light receiving surface of the first optical semiconductor element 11 may cover the first penetration hole 41, a light 26 transmitted from the outside passes through the second penetration hole 44 and the first penetration hole 41, and enters into the light receiving surface of the first optical semiconductor element 11.

An electrode, which is arranged in a peripheral portion of the light receiving surface of the first optical semiconductor element 11, is connected to the lead terminal 43a extending from the first mount bed 42. Another electrode, which is arranged on a side opposite to a light receiving surface, is connected to a signal input terminal of the first semiconductor chip 18 through a wire 20.

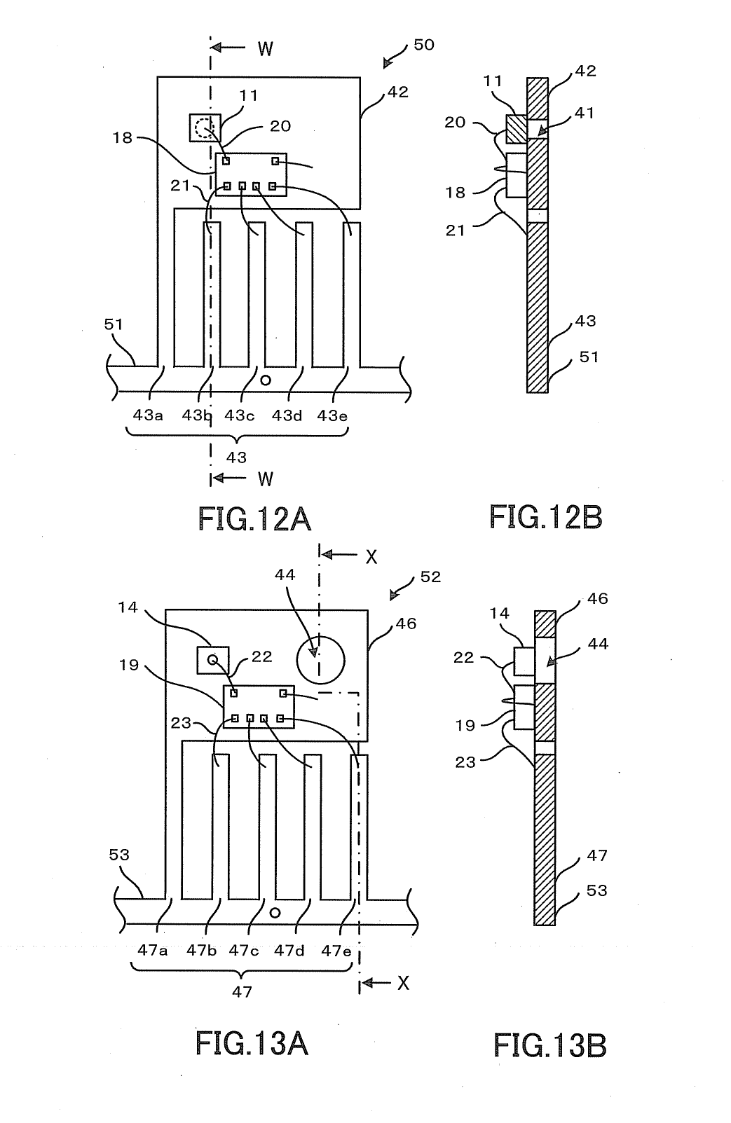

A method of manufacturing the optical semiconductor device 40 will be explained. FIG. 12A and FIG. 12B show a plan view and a view of section taken along a plane W-W of FIG. 12A, which show a manufacturing step of the second embodiment, respectively. FIG. 13A and FIG. 13B show a plain view and a view of section taken along a plane X-X of FIG. 13A, which show a manufacturing step of the second embodiment, respectively.

As shown in FIG. 12A, a first leadframe 50 is prepared. The first leadframe 50 has a first mount bed 42 which has a first penetration hole 41. The first leadframe 50 has a first lead terminal 43a, which extends from the first mount bed 42 in a direction and is used as a ground terminal. The first leadframe 50 has first lead terminals 43b to 43e arranged in parallel to the first lead terminal 43a. The first lead terminals 43a to 43e are connected by a tie bar 51.

A first optical semiconductor element 11 and a first semiconductor chip 18 are mounted on the first mount bed 42 using electrically conductive adhesive. The first optical semiconductor element 11 and a signal input terminal of the first semiconductor chip 18 are wire bonded with a wire 20. The first semiconductor chip 18 is wire bonded to the first lead terminals 43b to 43e with wires 21.

As shown in FIG. 13A, a second leadframe 52 is prepared. The second leadframe 52 has a second mount bed 46. The second mount bed 46 has a second penetration hole 44. The second leadframe 52 has a second lead terminal 47a which extends from the second mount bed 46 in a direction and is used as a ground terminal. The second leadframe 52 has second lead terminals 47b to 47e arranged in parallel to the second lead terminal 47a. The second lead terminals 47a to 47e is connected by a tie bar 53.

The second optical semiconductor device 14 and the second semiconductor chip 19 are mounted on the second mount bed 46 using electrically conductive adhesive. The second optical semiconductor element 14 and an output terminal of the second semiconductor chip 19 are wire bonded with a wire 22. The second semiconductor chip 19 is wire bonded to the second lead terminal 47b to 47e with wires 23.

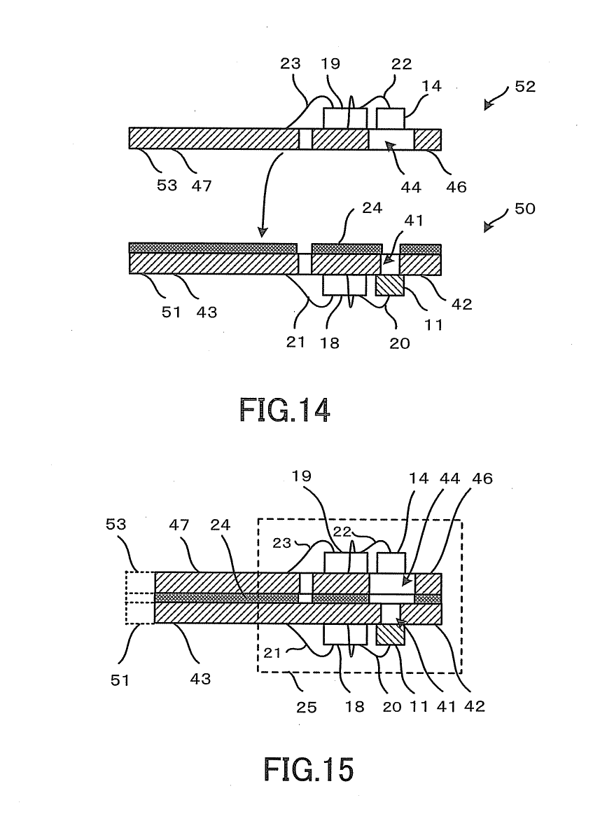

As shown in FIG. 14, an insulating paste as an insulating material 24 is applied onto the entire surface of the first leadframe 50.

The second leadframe 52 is arranged above the first leadframe 50 so as to be aligned with and opposite to the first leadframe 50. The second leadframe 52 is dropped down to the first leadframe 50. The first leadframe 50 and the second leadframe 52 are attached to each other back to back through the insulating material 24.

The insulating paste is cured. The first mount bed 42, the first lead terminals 43a to 43e, the tie bar 51, the first mount bed 46, the second lead terminals 47a to 47e and the tie bar 53 are fixed by the insulating material 24, respectively.

As shown in FIG. 15, the first and second optical semiconductor elements 11, 14, the first and second semiconductor chips 18, 19, and the first and second mount beds 42, 46 are molded to be integrated by a transparent resin 25, which allows light of a light emitting wavelength of the second optical semiconductor element 14.

After an opaque resin 25a is fitted in and fixed to the resin 25, the optical semiconductor device 40 is obtained by cutting the tie bars 51 and 53.

As the optical semiconductor device 40 of the embodiment, the first leadframe 50 is laminated on the second leadframe 52 back to back.

A distance is not always necessary between the first mount bed 42 and the second mount bed 46 so as to avoid contact of the wires 20 and 21 connected to the first optical semiconductor element 11 and the first semiconductor chip 18 with the second mount bed 46. Therefore, according to the embodiment, the depth D of the optical semiconductor device 40 can be shortened.

The embodiment can reduce the mounting area (D×W) of the optical semiconductor device 40 less than the first embodiment. Furthermore, since bending of the lead terminals is not required, manufacture of the optical semiconductor device 40 is easier.

In the embodiment, the first optical semiconductor element 11 is a light receiving element, and the second optical semiconductor element 14 is a light emitting element. The first optical semiconductor device 11 may be a light emitting element, and the second optical semiconductor element 14 may be a light receiving element.

Both of the first optical semiconductor element 11 and the second optical semiconductor element 14 may be light receiving elements or light emitting elements.

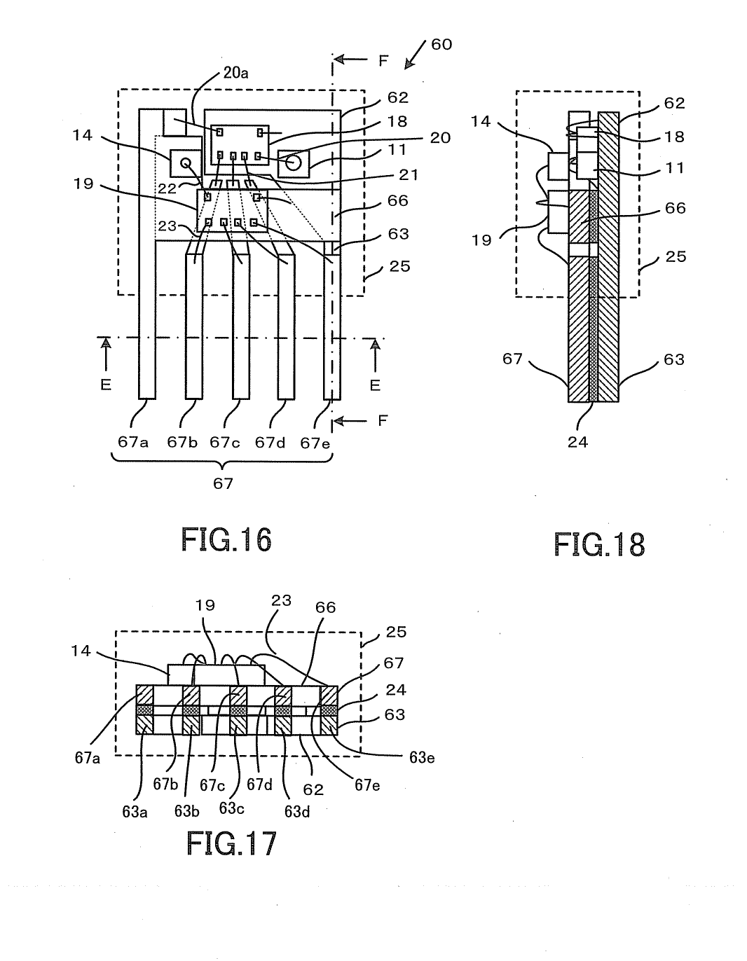

An optical semiconductor device of a third embodiment of the present invention will be explained. FIG. 16 is a plan view showing a third embodiment of an optical semiconductor device according to the present invention. FIG. 17 is a view of a section taken along a plane E-E of FIG. 16 and seen in a direction of an arrow. FIG. 18 is a view of a section taken along a plane F-F of FIG. 16 and seen in a direction of an arrow.

In the embodiment, the same reference numbers as those of the first embodiment designate the same portions.

In the embodiment, a first leadframe is laminated on a second leadframe to face in the same direction. First and second mount beds do not oppose to each other.

An optical semiconductor device 60 of the embodiment will be explained. A first optical semiconductor element 11 is mounted on a first mount bed 62. A light emitting or receiving surface of the first optical semiconductor element 11 faces upward. First lead terminal portion 63 are having first lead terminals 63a to 63e extended in the same plane as the first mount bed 62, and are electrically connected to the first optical semiconductor element 11 through first connection conductors.

A second mount bed 66 is placed on the first lead terminals 63a to 63e. The second mount bed 66 is fixed to the first lead terminals 63a to 63e via an insulating material 24. A light emitting or receiving surface of the second optical semiconductor element 14 faces upward. A portion of the second mount bed 66 is cut corresponding to the shape of the first mount bed 62 and the first lead terminals 63a to 63e.

Second lead terminals 67a to 67e are arranged around the second mount bed 66 to cover with the first lead terminals 63a to 63e. The second lead terminals 67a to 67e are electrically connected to the second optical semiconductor element 14 through second connection conductors. The second lead terminals 67a to 67e are placed on the first lead terminals 63a to 63e, and are fixed to the first lead terminal 63a to 63e via an insulating material 24.

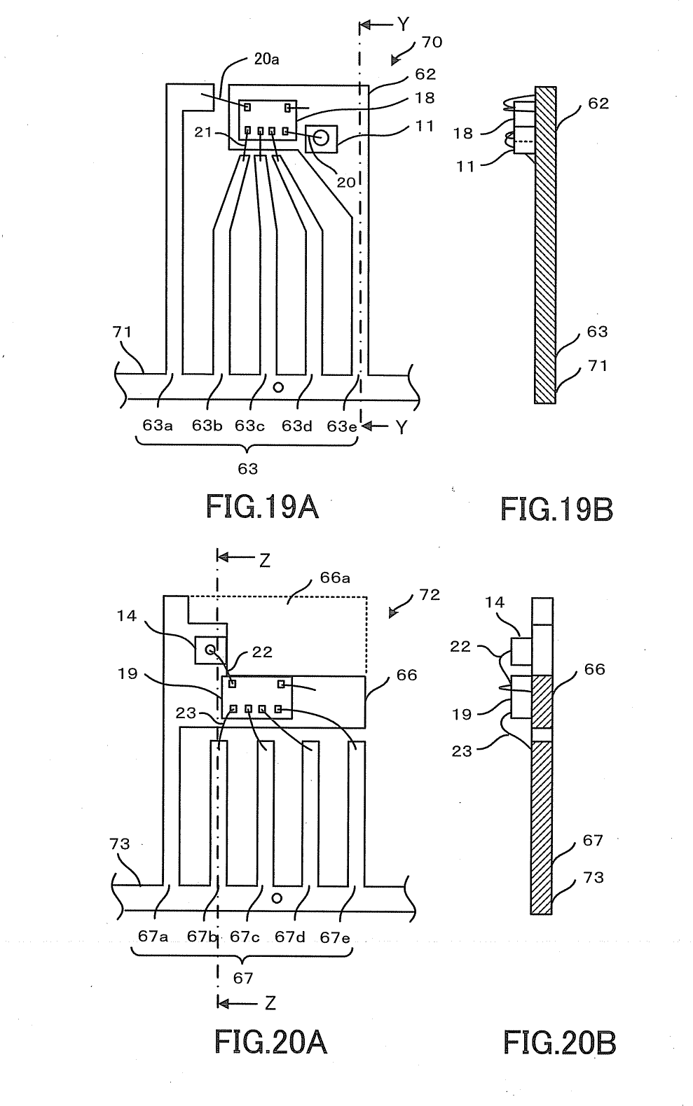

A method of manufacturing the optical semiconductor device 60 will be explained. FIG. 19A, and FIG. 19B show a plan view and a view of section taken along a plane Y-Y of FIG. 19A, which show a manufacturing step of the third embodiment, respectively. FIG. 20A and FIG. 20B show a plain view and a view of section taken along a plane V-V of FIG. 20A, which show a manufacturing step of the third embodiment, respectively.

As shown in FIG. 19A, a first leadframe 70 is prepared. The first leadframe 70 has a first mount bed 62. The first leadframe 70 has a first lead terminal 63e which extends from the first mount bed 62 in a direction and is used as a ground terminal. The first leadframe 70 has first lead terminals 63a to 63d arranged in parallel to the first lead terminal 63e. The first lead terminals 63a to 63e are connected by a tie bar 71.

The first optical semiconductor element 11 and the first semiconductor chip 18 are mounted on the first mount bed 62 using electrically conductive adhesive. The first optical semiconductor element 11 and a signal input terminal of the first semiconductor chip 18 are wire bonded with a wire 20. The first semiconductor chip 18 is wire bonded to the first lead terminals 63b to 63e with wires 21.

As shown in FIG. 20B, a second leadframe 72 is prepared. The second leadframe 72 has the second mount bed 66. A portion 66a of the second leadframe 72 is cut corresponding to the shape of the first mount bed 62 and the first lead terminals 63a to 63e. The second leadframe 72 has second lead terminals which extends from the second mount bed 66 in a direction, and is used as a ground terminal. The second leadframe has a second lead terminal 67a and the second lead terminals 67b to 67e arranged in parallel to the second lead terminal 67a. The second lead terminals 67a to 67e are connected by a tie bar 73.

The second optical semiconductor element 14 and the second semiconductor chip 19 are mounted on the second mount bed 66 using electrically conductive adhesive. The second optical semiconductor element 14 and an output terminal of the second semiconductor chip 19 are wire bonded with a wire 22. The second semiconductor chip 19 is wire bonded to the second lead terminals 67b to 67e with wires 23.

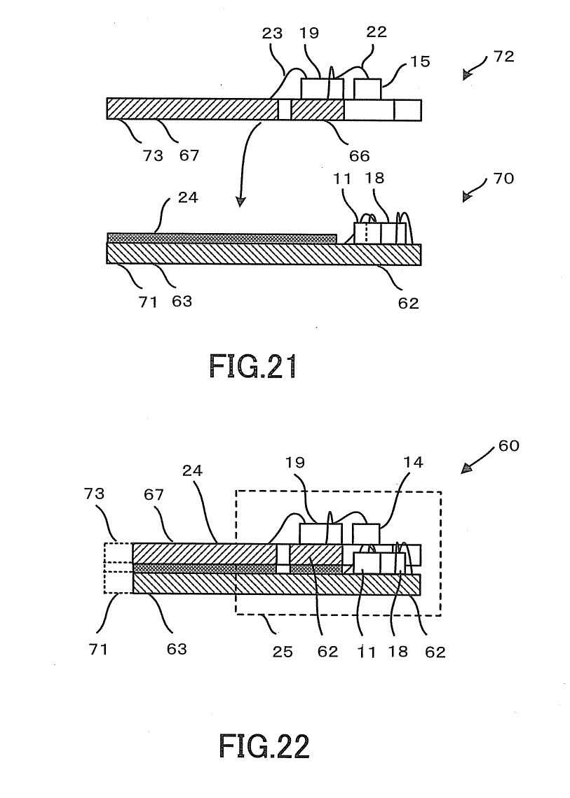

As shown in FIG. 21, an insulating paste, as an insulating material 24, is applied to the first lead terminal portion 63 of the first leadframe 70 except for a tip portion on which the element 11 is mounted.

The second leadframe 72 is arranged above the first leadframe 70 so as to overlap with the first leadframe 70. The second leadframe 74 is dropped down to the first leadframe 70. The first leadframe 70 and the second leadframe 72 are laminated via the insulating material 24 to face in the same direction.

The insulating paste is cured. The first lead terminal portion 63, the tie bar 71, the second lead terminal portion 67 and the tie bar 73 are fixed by the insulating material 24.

As shown in FIG. 22, the first and second optical semiconductor elements 11, 14, the first and second semiconductor chips 18, 19 and the first and second mount beds 62, 66 are molded to be integrated by the transparent resin 25, which transmit light of a light emitting wavelength of the second optical semiconductor element 14.

After an opaque resin 25a is fitted in and fixed to the resin 25, the optical semiconductor device 60 is obtained by cutting the tie bars 71, 73.

As explained above, the optical semiconductor device 60 of the embodiment has the first mount bed 62 and the second mount bed 66. A portion of the second mount bed 66 is cut corresponding to the tip portion of the first lead terminal portion 63. The second mount bed 66 is placed on the first lead terminal potion 63 so that the light emitting or light receiving surface of the first optical semiconductor element 11 cannot be covered by the second mount bed 66.

As a result, since the depth D of the optical semiconductor device 60 does not depend on the heights from the first mount bed 62 to the tops of the wires 20, 21, depth D of the optical semiconductor device 60 can be shortened further more. The embodiment can reduce the mounting area (D×W) of the optical semiconductor device 60 more than the second embodiment.

Other embodiments or modifications of the present invention will be apparent to those skilled in the art from consideration of the specification and practice of the invention disclosed herein. It is intended that the specification and example embodiments be considered as exemplary only, with a true scope and spirit of the invention being indicated by the following.

What is claimed is:

1. An optical semiconductor device comprising:
a first optical semiconductor element;
a first mount bed on which the first optical semiconductor element is mounted;
first lead terminals arranged around the first mount bed, the first lead terminals being electrically connected to the first optical semiconductor element through first connection conductors;
a second optical semiconductor element;
a second mount bed to mount a second optical semiconductor element, the second mount bed being arranged at an interval from the first optical semiconductor element and extending along the first mount bed, the second mount bed having a penetration hole at a portion corresponding to a light emitting or light receiving surface of the first optical semiconductor element; and
second lead terminals arranged around the second mount bed and extending along the first lead terminals, the second lead terminals being electrically connected to the second optical semiconductor element through second connection conductors, the second lead terminals being bent so as to be laminated on the first lead terminals, the second lead terminals being fixed to the first lead terminal at a portion via an insulating material.

2. The optical semiconductor device according to claim 1,
wherein the first and second optical semiconductor elements and the first and second mount beds are molded with resin and are integrated.

3. The optical semiconductor device according to claim 1,
wherein one of the first and the second optical semiconductor elements is a light receiving element, and the other of the first and the second optical semiconductor elements is a light emitting element.

4. The optical semiconductor device according to claim 3,
wherein the light receiving element is a photo diode, and the light emitting element is a LED or a semiconductor laser.

5. The optical semiconductor device according to claim 3,
wherein a first semiconductor chip for processing an output signal from the light receiving element is mounted on one of the first and the second mount beds to mount the light receiving element, and a second semiconductor chip for driving the light emitting element is mounted on the other of the first and the second mount beds to mount the light emitting element.

6. An optical semiconductor device comprising:
a first optical semiconductor element;
a first mount bed on which the first optical semiconductor element is mounted, the first mount bed having a first penetration hole which is covered with a light emitting or light receiving surface of the first optical semiconductor element;
first lead terminals arranged around the first mount bed, the first lead terminals being electrically connected to the first optical semiconductor element through first connection conductors;
a second optical semiconductor element;
a second mount bed to mount the second optical semiconductor element, the second mount bed being placed on a side opposite to the first optical semiconductor element and extending along the first mount bed, the second mount bed being fixed to first mount bed via an insulating material, the second mount bed having a second penetration hole at a portion corresponding to the first optical semiconductor element to expose the first penetration hole; and
second lead terminals arranged around the second mount bed and extending along the first lead terminals, the second lead terminals being electrically connected to the second optical semiconductor element through second connection conductors, the second lead terminals being laminated on and fixed to the first lead terminal via the insulating material.

7. The optical semiconductor device according to claim 6,
wherein the first and second optical semiconductor elements and the first and second mount beds are molded with resin and are integrated.

8. The optical semiconductor device according to claim 6,
wherein one of the first and the second optical semiconductor elements is a light receiving element, and the other of the first and the second optical semiconductor element is a light emitting element.

9. The optical semiconductor device according to claim 8,
wherein the light receiving element is a photo diode, and the light emitting element is a LED or a semiconductor laser.

10. The optical semiconductor device according to claim 8,
wherein a first semiconductor chip that for processing an output signal from the light receiving element is mounted on one of the first and the second mount beds to mount the light receiving element, and a second semiconductor chip for driving the light emitting element is mounted on the other of the first and the second mount beds to mount the light emitting element.

11. An optical semiconductor device comprising:
a first optical semiconductor element;
a first mount bed on which the first optical semiconductor element is mounted;
first lead terminals arranged around the first mount bed, the first lead terminals being electrically connected to the first optical semiconductor element through first connection conductors;
a second optical semiconductor element;
a second mount bed to mount a second optical semiconductor element, the second mount bed being placed on the first lead terminals and extending in the same direction as the first mount bed, the second mount bed being fixed to the first lead terminals via an insulating material, a portion of the second mount bed being cut corresponding to the areas of the first mount bed and end portions of the first lead terminals; and
second lead terminals arranged around the second mount bed and extending along the first lead terminals, the second lead terminals being fixed to the first lead terminals via the insulating material, the second lead terminals being laminated on the first lead terminal and connected to the second optical semiconductor element through second connection conductors.

12. The optical semiconductor device according to claim 11,
wherein the first and second optical semiconductor elements and the first and second mount beds are molded with and are integrated.

13. The optical semiconductor device according to claim 11,
wherein one of the first and the second optical semiconductor elements is a light receiving element, and the other of the first and the second optical semiconductor elements is a light emitting element.

14. The optical semiconductor device according to claim 13,
wherein the light receiving element is a photo diode, and the light emitting element is a LED or a semiconductor laser.

15. The optical semiconductor device according to claim 13,
wherein a first semiconductor chip for processing an output signal from the light receiving element is mounted on one of the first and the second mount beds to mount the light receiving element, and a second semiconductor chip for driving the light emitting element is mounted on the other of the first and the second mount beds to mount the light emitting element.
